(19) United States
(12) Patent Application Publication
(10) Pub. No.: US 2026/0066004 A1
(43) Pub. Date: Mar. 5, 2026

(54) TAIL CURRENT BIAS FOR SENSE OPERATIONS IN A MEMORY DEVICE

(71) Applicant: Micron Technology, Inc., Boise, ID (US)

(72) Inventors: Ferdinando Bedeschi, Biassono (IT); Umberto Di Vincenzo, Capriate (IT); Riccardo Muzzetto, Arcore (IT); Walter Di Francesco, Avezzano (IT); Tomoharu Tanaka, Yokohama (JP)

(21) Appl. No.: 19/306,797

(22) Filed: Aug. 21, 2025

Related U.S. Application Data
(60) Provisional application No. 63/687,706, filed on Aug. 27, 2024.

(51) Int. Cl. G11C 16/26; G11C 16/24; G11C 16/30

(52) U.S. Cl. CPC G11C 16/26; G11C 16/24; G11C 16/30

(57) ABSTRACT

A memory device includes a memory array with a plurality of memory cells formed at respective intersections of a plurality of wordlines and a plurality of bit lines. The memory device further includes a page buffer circuit coupled to the memory array, the page buffer circuit comprising sense circuitry to measure a cell current read from a bitline of the plurality of bitlines and tail current bias circuitry coupled to the bitline, wherein the tail current bias circuitry comprises a tail current capacitor having a first terminal coupled to the bitline, the tail current capacitor to generate a tail current in the bitline during a signal integration period when the sense circuitry measures the cell current read from the bitline.

### RELATED APPLICATIONS

This application claims the benefit of U.S. Provisional Patent Application No. 63/687,706, filed Aug. 27, 2024, the entire contents of which are hereby incorporated by reference herein.

### TECHNICAL FIELD

Embodiments of the disclosure relate generally to memory sub-systems, and more specifically, relate to tail current bias for sense operations in a memory device of a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system in accordance with some embodiments of the present disclosure.

FIG. 1B is a block diagram of a memory device in communication with a memory sub-system controller of a memory sub-system, in accordance with some embodiments of the present disclosure.

FIG. 2 is a schematic of portions of an array of memory cells as could be used in a memory of the type described with reference to FIG. 1B in accordance with some embodiments of the present disclosure.

FIG. 3A is a schematic illustrating portions of a page buffer circuit with tail current bias circuitry, and FIG. 3B is a timing diagram for the same, in accordance with some embodiments of the present disclosure.

FIG. 4A is a schematic illustrating portions of a page buffer circuit with tail current bias circuitry, and FIG. 4B is a timing diagram for the same, in accordance with some embodiments of the present disclosure.

FIG. 5 is a flow diagram of an example method of performing sense operations in a memory device using tail current bias in accordance with some embodiments of the present disclosure.

FIG. 6A is a schematic illustrating portions of a page buffer circuit with switched tail current bias circuitry, and FIG. 6B is a timing diagram for the same, in accordance with some embodiments of the present disclosure.

FIG. 7A is a schematic illustrating portions of a page buffer circuit with switched tail current bias circuitry, and FIG. 7B is a timing diagram for the same, in accordance with some embodiments of the present disclosure.

FIG. 8A is a schematic illustrating portions of a page buffer circuit with switched tail current bias circuitry, and FIG. 8B is a timing diagram for the same, in accordance with some embodiments of the present disclosure.

FIG. 9A is a schematic illustrating portions of a page buffer circuit with switched tail current bias circuitry, and FIG. 9B is a timing diagram for the same, in accordance with some embodiments of the present disclosure.

FIG. 10A is a schematic illustrating portions of a page buffer circuit with switched tail current bias circuitry, and FIG. 10B is a timing diagram for the same, in accordance with some embodiments of the present disclosure.

FIG. 11 is a block diagram of an example computer system in which embodiments of the present disclosure can operate.

### DETAILED DESCRIPTION

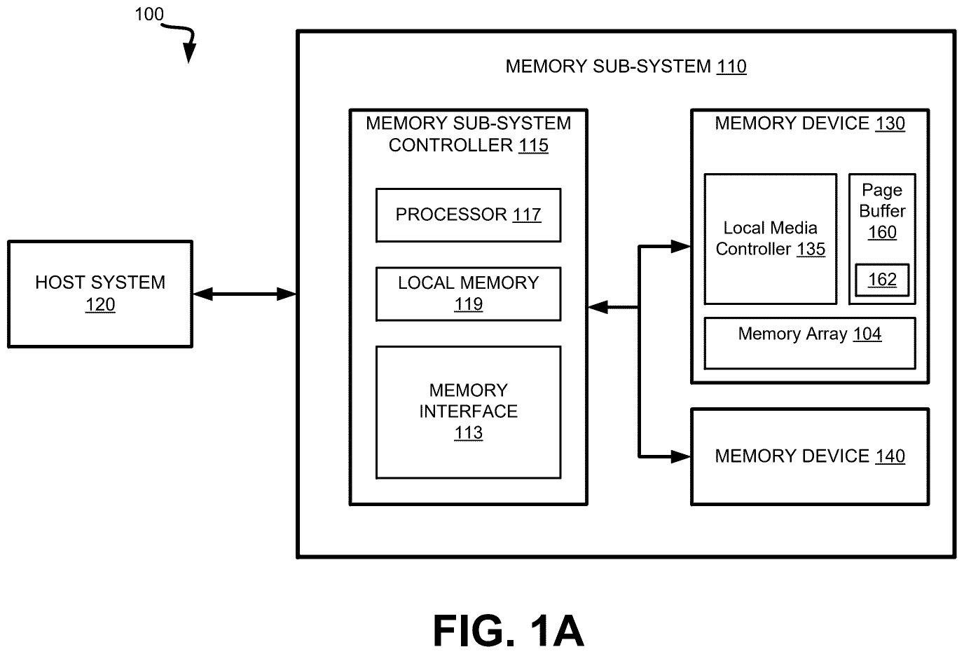

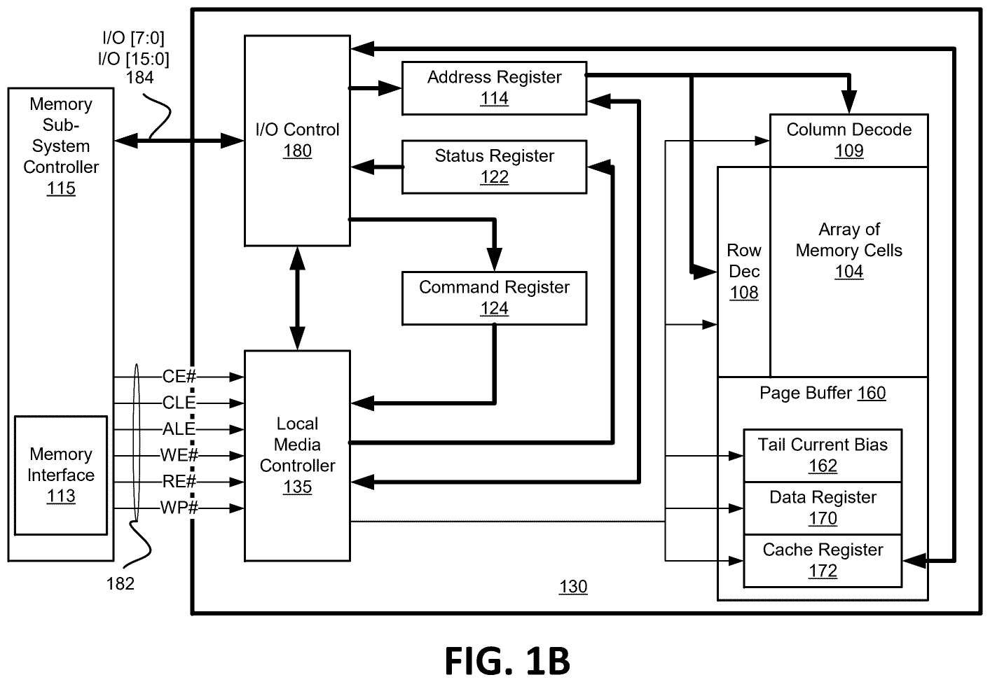

Aspects of the present disclosure are directed to tail current bias for sense operations in a memory device of a memory sub-system. A memory sub-system can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more dice, each including one or more planes. For some types of non-volatile memory devices (e.g., NAND memory), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

As part of the read operation, a page buffer circuit in the memory device can be used to sense the levels of charge stored in selected memory cells of the memory array. The page buffer circuit can first precharge the bitlines to a known voltage, and then when a read voltage is applied to the selected wordline, the page buffer circuit can sense the bitline voltage, which may either remain high or discharge based on the threshold voltage of the memory cell being read. For example, to sense the bitline voltage, a current flowing on the bitline can be integrated over time using a temporary cache capacitor. As the current flows, it charges or discharges the capacitor, and this change corresponds to a change in the bitline voltage. The page buffer circuit compares the bitline voltage to a reference voltage to determine if the cell is in a programmed state (e.g. ‘0’) or an erased state (e.g., ‘1’), and the result can be stored in a latch temporarily until it is transferred out or further processed.

The sensing operations performed in the page buffer are sensitive to a number of factors that can negatively impact accuracy, including noise, interference, and process variations. For example, pattern noise can arise from the influence of the data patterns stored in adjacent cells or nearby memory pages in the array. This noise can be caused by coupling between cells (i.e., inter-cell interference), variations in the cells' threshold voltages, or read/write disturbs due to repeated operations in nearby cells. Pattern noise introduces variability in the threshold voltages of the memory cells, and the bitline voltage can be affected by the noise from adjacent cells, leading to incorrect voltage readings during sensing. Thus, the page buffer circuit may not be able to accurately distinguish between the programmed and erased states, leading to bit errors and incorrect reading of the stored data.

Aspects of the present disclosure address the above and other deficiencies by implementing tail current bias for sense operations in a memory device of a memory sub-system. For example, the page buffer circuit can include a tail current capacitor, or a network of one or more capacitors and/or switches (e.g., transistors), that is coupled to the bitline and is used to generate a tail current during the sense operation (e.g., as part of a read or program verify operation). In one embodiment, the one or more tail current capacitors are biased with a voltage signal that can be ramped down during the signal integration time, thereby generating the tail current on the bitline. The tail current, from a sense point of view, is added to the cell current during the sensing phase to increase the accuracy of the sensing. When the sense reads a cell programmed to a logical 0 (i.e., a cell that doesn't absorb current) the convergence of the bitline becomes faster. Once the bitline reaches a steady state, both the cell current from the bitline and the tail current can be integrated at a temporary cache capacitor, causing the voltage at the temporary cache node to drop. The rate at which the voltage drops can be used to identify the state of the cell being read from the bitline. The presence of the tail current stabilizes the bitline, thereby reducing variability, increasing the signal to noise ratio, and allowing a detector in the page buffer to more accurately distinguish between a programmed state (e.g. ‘0’) and an erased state (e.g., ‘1’). In other embodiments, a switched tail current capacitor is used to generate the tail current on the bitline. In these embodiments, a network of switches, controlled by alternating control signals, alternately charges the tail current capacitor from the bitline and discharges the tail current capacitor to a source node (e.g., ground). The frequency of the switching can be used to more accurately control the magnitude of the tail current, which further improves the accuracy of the sense operation in the page buffer circuit.

Advantages of the approaches described herein include, but are not limited to, improved performance in the page buffer circuit of the memory device. The use of the tail current bias, in any embodiment, increases the accuracy of the sense operation. When used with a ramping bias signal, the tail current capacitor allows for a lower precharge time, higher fringe disturb immunity, and lower headroom than sense operations performed without such a tail current. The switched capacitor solution offers further advantages of increased flexibility for tail current generation, decreased area as a ramp generator is not required and a smaller tail current capacitor can be used, and an increased read window due to disturb cancellation effects.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the physical host interface (e.g., PCIe or CXL interface). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, the memory sub-system 110 includes a memory interface 113 that is responsible for handling interactions of memory sub-system controller 115 with the memory devices of memory sub-system 110, such as memory device 130. For example, the memory interface 113 can send memory access commands corresponding to requests received from host system 120 to memory device 130, such as program commands, read commands, or other commands. In addition, the memory interface 113 can receive data from memory device 130, such as data retrieved in response to a read command or a confirmation that a program command was successfully performed. In some embodiments, the memory sub-system controller 115 includes at least a portion of the memory interface 113. For example, the memory sub-system controller 115 can include a processor 117 (processing device) configured to execute instructions stored in local memory 119 for performing the operations described herein.

In one embodiment, local media controller 135 of memory device 130 can manage the memory access operations performed on the memory cells in memory array 104 of memory device 130. For example, local media controller 135 can provide control signals to drivers or other circuitry associated with memory array 104, including page buffer circuit 160. In one embodiment, as part of the read operation or a program verify operation, page buffer circuit 160 can include sense circuitry, which can be used to sense the levels of charge stored in selected memory cells of the memory array 104. The page buffer circuit can first precharge a selected bitline of the memory array 104 to a known voltage, and then when a read voltage is applied to a selected wordline of the memory array 104, the page buffer circuit 160 can sense the bitline voltage, which may either remain high or discharge based on the threshold voltage of the memory cell being read. In one embodiment, the page buffer circuit 160 includes tail current bias circuitry 162 to improve sense operations in memory device 130. For example, as described in more detail below, the tail current bias circuitry 162 can include a tail current capacitor, or a network of one or more capacitors and/or switches (e.g., transistors), that is coupled to the bitline and is used to generate a tail current during the sense operation (e.g., as part of a read or program verify operation). In one embodiment, the one or more tail current capacitors are biased with a voltage signal that can be ramped down during the signal integration time, thereby generating the tail current on the bitline. Once the bitline reaches a steady state, both the cell current from the bitline and the tail current can be integrated at a temporary cache capacitor, causing the voltage at the temporary cache node to drop. The rate at which the voltage drops can be used to identify the state of the cell being read from the bitline. The presence of the tail current stabilizes the bitline, thereby reducing variability, increasing the signal to noise ratio, and allowing a detector in the page buffer to more accurately distinguish between a programmed state (e.g. ‘0’) and an erased state (e.g., ‘1’). In other embodiments, a switched tail current capacitor is used to generate the tail current on the bitline. In these embodiments, a network of switches, controlled by alternating control signals, alternately charges the tail current capacitor from the bitline and discharges the tail current capacitor to a source node (e.g., ground). The frequency of the switching can be used to more accurately control the magnitude of the tail current, which further improves the accuracy of the sense operation in the page buffer circuit. Further details with regards to the operations of local media controller 135, page buffer circuit 160, and tail current bias circuitry 162 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. In one embodiment, memory sub-system controller 115 includes memory interface 113.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 180 to manage input of commands, addresses and data to the memory device 130 as well as output of data and status information from the memory device 130. An address register 114 is in communication with I/O control circuitry 180 and row decode circuitry 108 and column decode circuitry 109 to latch the address signals prior to decoding. A command register 124 is in communication with I/O control circuitry 180 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 180. During a read operation, data may be passed from the cache register 172 to the I/O control circuitry 180 for output to the memory sub-system controller 115; then new data may be passed from the data register 170 to the cache register 172. The cache register 172 and/or the data register 170 may form (e.g., may form a portion of) a page buffer 160 of the memory device 130. The page buffer 160 may further include sensing devices (e.g., included within page buffer 160) to sense a data state of a memory cell of the array of memory cells 104 (e.g., by sensing a state of a data line (i.e., bitline) connected to that memory cell). A status register 122 may be in communication with I/O control circuitry 180 and the local memory controller 135 to latch the status information for output to the memory sub-system controller 115. In addition, the page buffer 160 may include tail current bias circuitry 162 which can generate a tail current on the bitline during sense operations to improve accuracy of sensing a given data state from the memory cells of the array 104.

Memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

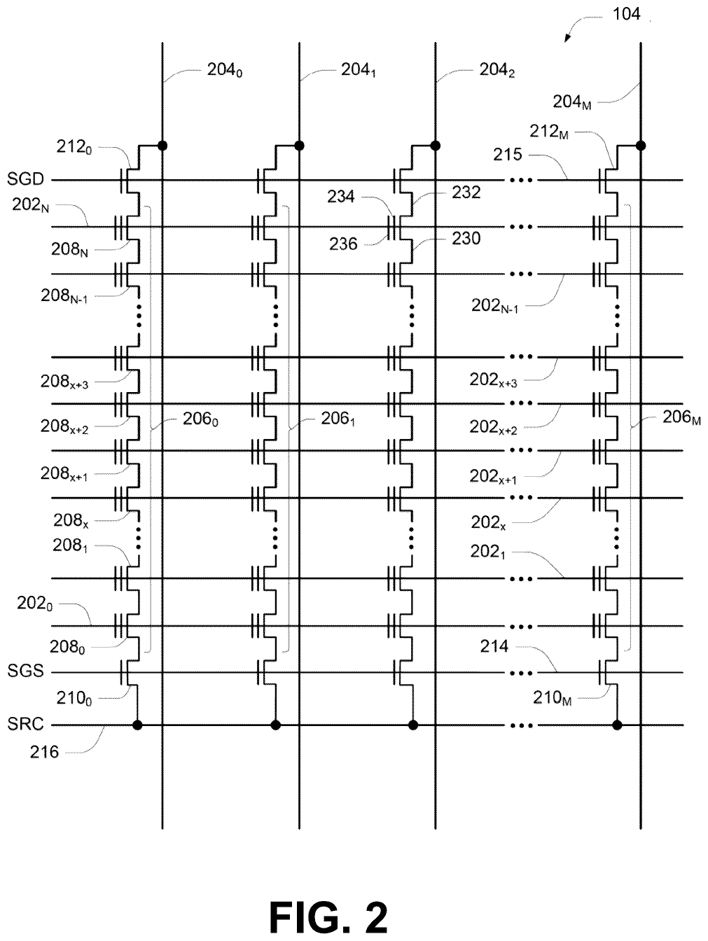

FIG. 2 is a schematic of portions of an array of memory cells 104, such as a NAND memory array, as could be used in a memory of the type described with reference to FIG. 1B according to an embodiment. Memory array 104 includes access lines, such as wordlines 202₀ to 202_{N}, and data lines, such as bitlines 204₀ to 204_{M}. The wordlines 202 can be connected to global access lines (e.g., global wordlines), not shown in FIG. 2, in a many-to-one relationship. For some embodiments, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 212₀ can be connected to the bitline 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bitline 204. A control gate of each select gate 212 can be connected to select line 215.

The memory array 104 in FIG. 2 can be a quasi-two-dimensional memory array and can have a generally planar structure, e.g., where the common source 216, NAND strings 206 and bitlines 204 extend in substantially parallel planes. Alternatively, the memory array 104 in FIG. 2 can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bitlines 204 (e.g., bitlines 204₀, 204₂, 204₄, etc.) can be one physical page of the memory cells 208 (e.g., even memory cells) while memory cells 208 commonly connected to wordline 202_{N} and selectively connected to odd bitlines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2, it is apparent from the figure that the bitlines 204 of the array of memory cells 104 can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

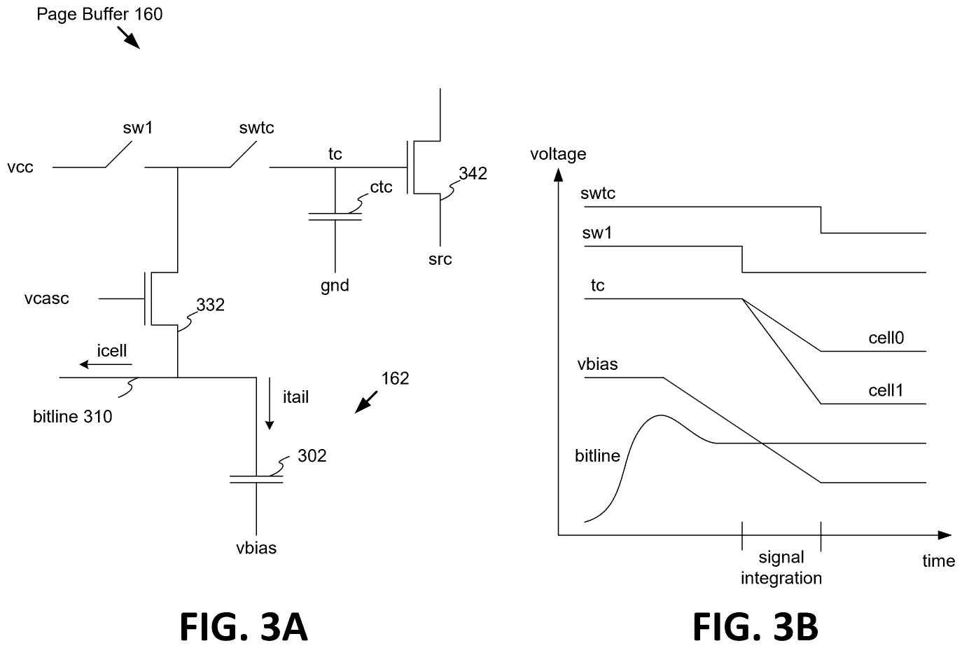

FIG. 3A is a schematic illustrating portions of a page buffer circuit with tail current bias circuitry, and FIG. 3B is a timing diagram for the same, in accordance with some embodiments of the present disclosure. For example, the page buffer 160 associated with the memory array 104 of memory device 130 can include tail current bias circuitry 162 corresponding to each bitline, and thus to each vertical string of memory cells, in the array 104. In the illustrated embodiment, tail current bias circuitry 162 includes tail current capacitor 302, with one terminal connected to the bitline 310 in memory array 104, and another terminal that is biased with a voltage signal (vbias). In one embodiment, this voltage signal is received from a signal generator (not shown) and can be ramped down over time from an initial voltage level to a lower voltage level, as shown in the timing diagram of FIG. 3B. In one embodiment, page buffer circuit 160 further includes sense circuitry to sense the voltage read from bitline 332 based on the cell current (icell). In one embodiment, the sense circuitry includes a cascode transistor, a number of switches, a temporary cache capacitor (ctc), and a detector transistor 342. The bitline 310 can initially be precharged via a voltage signal received via cascode transistor 332, which is controlled by a control signal (vcasc), from the voltage supply (vcc) when a first switch (sw1) is active. As the voltage signal (vbias) is ramped down, a tail current (itail) is generated in bitline 310 to charge tail current capacitor 302. As the voltage on bitline 310 reaches a steady state, the first switch (sw1) can be deactivated, while a second switch (swtc) remains active, in order to begin a signal integration period. During the signal integration period, both a cell current (icell) from the bitline and the tail current (itail) can be integrated at a temporary cache capacitor (ctc), causing the voltage at the temporary cache (tc) node to drop. A detector transistor 342 can be used to sample the voltage at the temporary cache (tc) node during the signal integration period. As illustrated in FIG. 3B, the rate at which the voltage at the temporary cache (tc) node drops can be used to identify the state of the cell being read from the bitline 310. A lower voltage (cell1) will represent a cell programmed to a logical ‘1’ and a higher voltage (cell0) will represent a cell programmed to a logical ‘0’. Deactivating the second switch (swtc) ends the signal integration period.

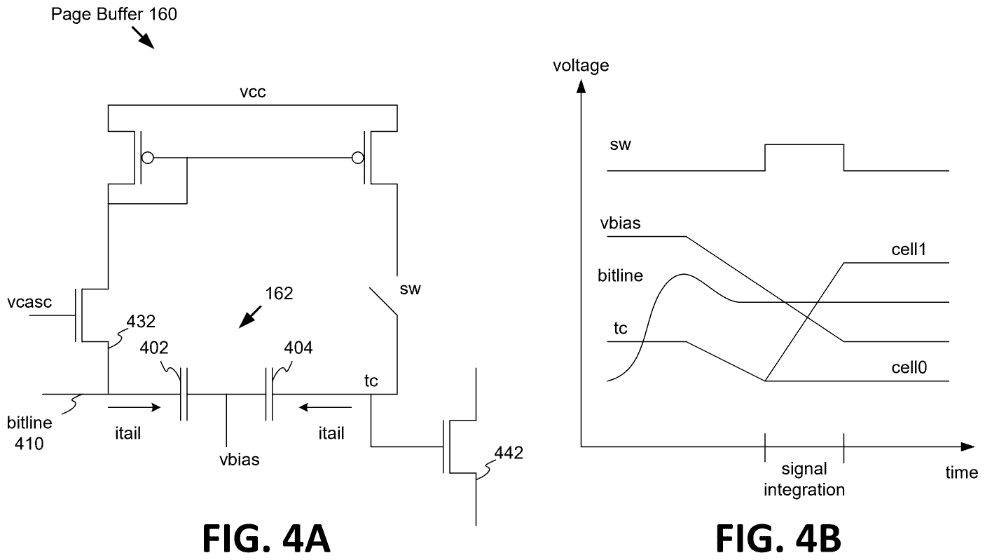

FIG. 4A is a schematic illustrating portions of a page buffer circuit with tail current bias circuitry, and FIG. 4B is a timing diagram for the same, in accordance with some embodiments of the present disclosure. For example, the page buffer 160 associated with the memory array 104 of memory device 130 can include tail current bias circuitry 162 corresponding to each bitline, and thus to each vertical string of memory cells, in the array 104. In the illustrated embodiment, tail current bias circuitry 162 includes two tail current capacitors 402 and 404. One terminal of capacitor 402 is connected to the bitline 410 in memory array 104, and another terminal is biased with a voltage signal (vbias). One terminal of capacitor 404 is connected to the temporary cache (tc) node, and another terminal is biased with the voltage signal (vbias). As described above, this voltage signal is received from a signal generator (not shown) and can be ramped down over time from an initial voltage level to a lower voltage level, as shown in the timing diagram of FIG. 4B. The bitline 410 can initially be precharged via a voltage signal received via cascode transistor 432, which is controlled by a control signal (vcasc), from the voltage supply (vcc). As the voltage signal (vbias) is ramped down, a tail current (itail) is generated in bitline 410 to charge tail current capacitor 402 and is drawn from the temporary cache (tc) node to charge tail current capacitor 404. As the voltage on bitline 410 reaches a steady state, a switch (sw) can be activated in order to begin a signal integration period. During the signal integration period, the current at the temporary cache (tc) node is integrated, causing the voltage at the temporary cache (tc) node to increase. This current at the temporary cache (tc) node represents the cell current (icell) from the bitline 410 as the tail current (itail) from the second capacitor 404 will compensate for the cell current (icell) added by the first capacitor 402. A detector transistor 442 can be used to sample the voltage at the temporary cache (tc) node during the signal integration period. As illustrated in FIG. 4B, the rate at which the voltage at the temporary cache (tc) node increases can be used to identify the state of the cell being read from the bitline 310. A lower voltage (cell0) will represent a cell programmed to a logical ‘0’ and a higher voltage (cell1) will represent a cell programmed to a logical ‘1’. Deactivating the switch (sw) ends the signal integration period.

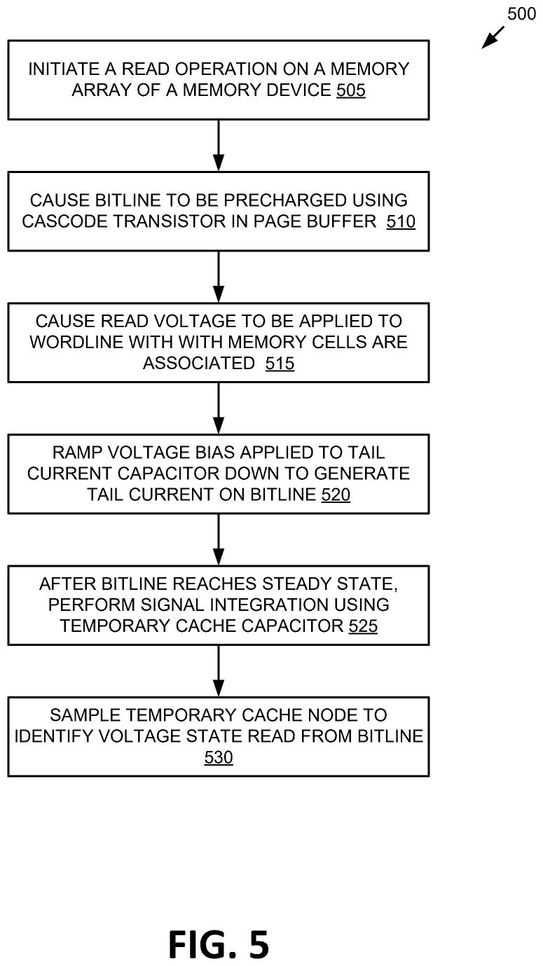

FIG. 5 is a flow diagram of an example method of performing sense operations in a memory device using tail current bias in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by one or more of memory sub-system controller 115, local media controller 135, and page buffer circuit 160 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 505, a read operation is initiated. For example, the processing logic (e.g., memory sub-system controller 115) can initiate a read operation on a memory array 104 of memory device 130. Depending on the embodiment, the read operation can be initiated in response to a received request (e.g., from host system 120) or can be a program verify operation (i.e., to confirm that data was properly programmed to the memory array 104). The read operation can be directed to a specific memory address in the memory array 104, such as to one or more memory cells located at the intersection of one or more wordlines and one or more bitlines of the memory array 104.

At operations 510, a bitline is precharged. For example, the processing logic (e.g., local media controller 135) can send a control signal (e.g., vcasc) to the page buffer circuit 160 to activate a cascode transistor, such as 332 or 432, which permits a voltage signal to precharge a selected bitline, such as 310 or 410, associated with the one or more memory cells to be read.

At operation 515, a read voltage is applied. For example, the processing logic (e.g., local media controller 135) can send a control signal to associated signal drivers to cause a read voltage signal to be applied to a selected wordline of the memory array 104 associated with the one or more memory cells to be read.

At operation 520, a voltage signal is ramped. For example, the processing logic (e.g., local media controller 135) can send a control signal to associated signal drivers to cause the voltage signal (vbias) applied to one terminal of a tail current capacitor, such as 302, 402, and/or 404, coupled to the bitline 310 or 410 to ramp down over time from an initial voltage level to a lower voltage level. As the voltage signal (vbias) is ramped down, a tail current (itail) is generated in bitline 310 to charge tail current capacitor 302 or in bitline 410 to charge tail current capacitor 402 and is drawn from the temporary cache (tc) node to charge tail current capacitor 404.

At operation 525, signal integration is performed. For example, the processing logic (e.g., local media controller 135) can send a control signal to the page buffer circuit 160 to deactivate a switch (sw1), as shown in FIG. 3A, or activate a switch (sw), as shown in FIG. 4A, in order to initiate a signal integration period. In one embodiment, during the signal integration period, both a cell current (icell) from the bitline and the tail current (itail) can be integrated at a temporary cache capacitor (ctc), causing the voltage at the temporary cache (tc) node to drop. In another embodiment, the current at the temporary cache (tc) node is integrated, causing the voltage at the temporary cache (tc) node to increase.

At operation 530, a voltage is sampled. For example, the processing logic (e.g., local media controller 135) can send a control signal to the page buffer circuit 160 to cause a detector transistor, such as 342 or 442, to sample the voltage at the temporary cache (tc) node during the signal integration period. As illustrated in FIG. 3B, the rate at which the voltage at the temporary cache (tc) node drops can be used to identify the state of the cell being read from the bitline 310. A lower voltage (cell1) will represent a cell programmed to a logical ‘1’ and a higher voltage (cell0) will represent a cell programmed to a logical ‘0’. As illustrated in FIG. 4B, the rate at which the voltage at the temporary cache (tc) node increases can be used to identify the state of the cell being read from the bitline 310. A lower voltage (cell0) will represent a cell programmed to a logical ‘0’ and a higher voltage (cell1) will represent a cell programmed to a logical ‘1’.

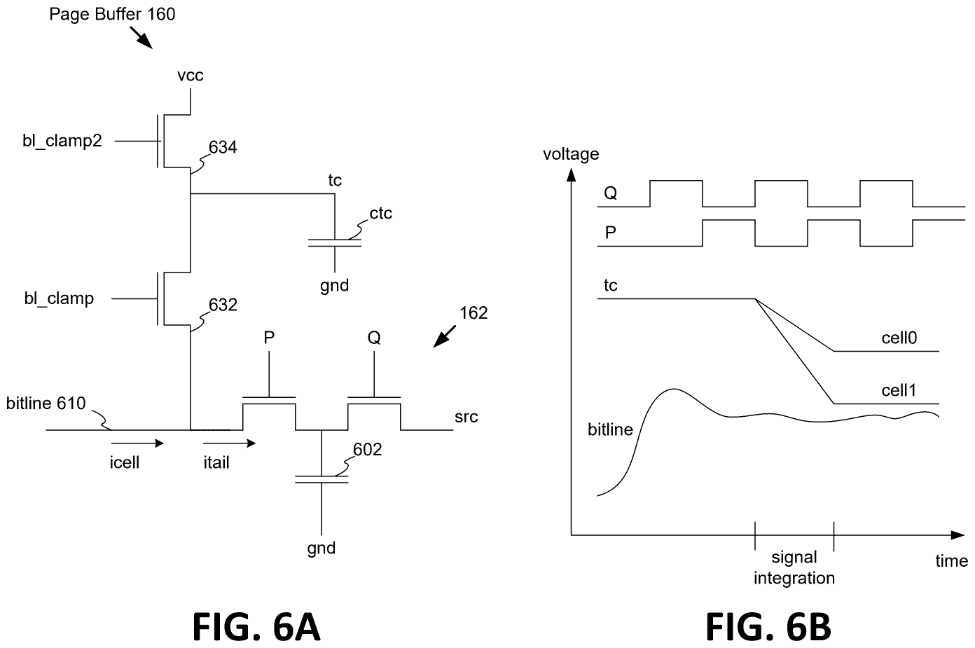

FIG. 6A is a schematic illustrating portions of a page buffer circuit with switched tail current bias circuitry, and FIG. 6B is a timing diagram for the same, in accordance with some embodiments of the present disclosure. For example, the page buffer 160 associated with the memory array 104 of memory device 130 can include tail current bias circuitry 162 corresponding to each bitline, and thus to each vertical string of memory cells, in the array 104. In the illustrated embodiment, tail current bias circuitry 162 includes tail current capacitor 602, with one terminal connected to the bitline 610 in memory array 104 via a network of switches (e.g., transistors), and another terminal that is coupled to ground (gnd). In one embodiment, the switches by which the tail current capacitor 602 is coupled to the bitline are controlled by alternating control signals (P and Q), as shown in the timing diagram of FIG. 6B. The bitline 610 can initially be precharged via a voltage signal received via transistors 632 and 634, which are respectively controlled by control signals bl_clamp and bl_clamp 2, from the voltage supply (vcc). The switches controlled by control signals P and Q alternately charge the tail current capacitor 602 from the bitline 610 and discharge the tail current capacitor to a source node (e.g., ground), thereby generating a tail current (itail) in bitline 610. For example, when the control signal P is active, the tail current (itail) is generated in bitline 610 to charge tail current capacitor 602, and when the control signal Q is active, the tail current capacitor 602 is discharged to the source node. The frequency of the switching of P and Q can be used to control the magnitude of the tail current (itail). As the voltage on bitline 610 reaches a steady state, a signal integration period can begin during which, both a cell current (icell) from the bitline and the tail current (itail) can be integrated at a temporary cache capacitor (ctc), causing the voltage at the temporary cache (tc) node to drop. The voltage at the temporary cache (tc) node can be sampled during the signal integration period to determine the state of the cell being read. As illustrated in FIG. 6B, the rate at which the voltage at the temporary cache (tc) node drops can be used to identify the state of the cell being read from the bitline 610. A lower voltage (cell1) will represent a cell programmed to a logical ‘1’ and a higher voltage (cell0) will represent a cell programmed to a logical ‘0’.

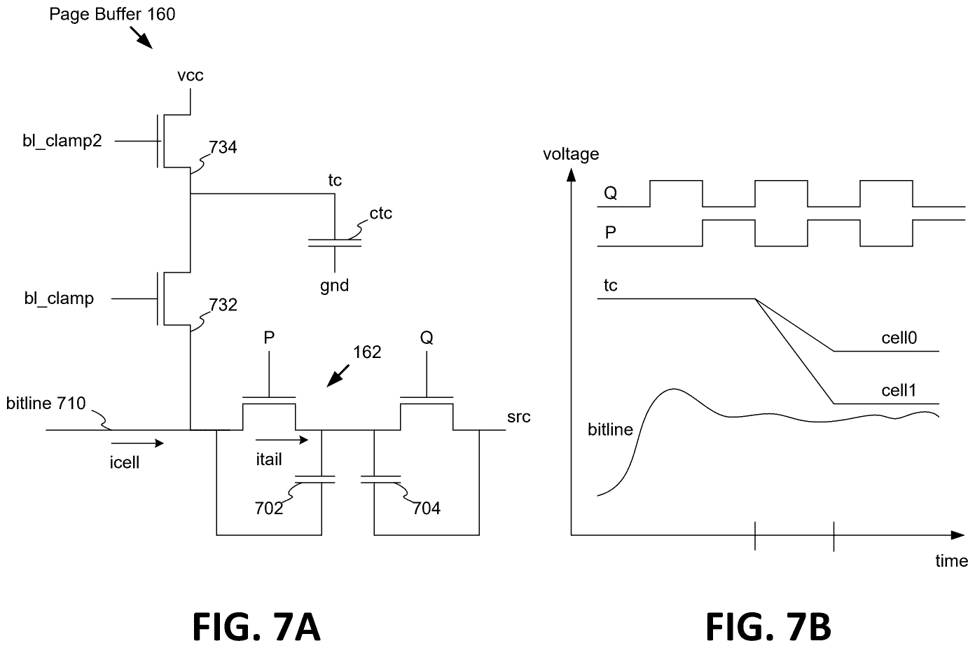

FIG. 7A is a schematic illustrating portions of a page buffer circuit with switched tail current bias circuitry, and FIG. 7B is a timing diagram for the same, in accordance with some embodiments of the present disclosure. For example, the page buffer 160 associated with the memory array 104 of memory device 130 can include tail current bias circuitry 162 corresponding to each bitline, and thus to each vertical string of memory cells, in the array 104. In the illustrated embodiment, tail current bias circuitry 162 includes two tail current capacitors 702 and 704. One terminal of capacitor 702 is connected to bitline 710, and another terminal is coupled on the opposite side of a first switch controlled by control signal P. One terminal of capacitor 704 is connected to a source node (e.g., ground), and another terminal is coupled on the opposite side of a second switch controlled by control signal Q. In one embodiment, the switches are controlled by alternating control signals (P and Q), as shown in the timing diagram of FIG. 7B. The bitline 710 can initially be precharged via a voltage signal received via transistors 732 and 734, which are respectively controlled by control signals bl_clamp and bl_clamp 2, from the voltage supply (vcc). The switches controlled by control signals P and Q alternately charge the tail current capacitors 702 and 704 from the bitline 710 and discharge them to the source node (e.g., ground), thereby generating a tail current (itail) in bitline 710. For example, when the control signal P is active, the tail current (itail) is generated in bitline 710 to charge tail current capacitors 702 and 704, and when the control signal Q is active, the tail current capacitors 702 and 704 are discharged to the source node. In this manner, tail current capacitors 702 and 704 are short circuited one at a time to avoid disturb on the bitline because of the discharge that happens between the two pins. The frequency of the switching of P and Q can be used to control the magnitude of the tail current (itail). As the voltage on bitline 710 reaches a steady state, a signal integration period can begin during which, both a cell current (icell) from the bitline and the tail current (itail) can be integrated at a temporary cache capacitor (ctc), causing the voltage at the temporary cache (tc) node to drop. The voltage at the temporary cache (tc) node can be sampled during the signal integration period to determine the state of the cell being read. As illustrated in FIG. 7B, the rate at which the voltage at the temporary cache (tc) node drops can be used to identify the state of the cell being read from the bitline 710. A lower voltage (cell1) will represent a cell programmed to a logical ‘1’ and a higher voltage (cell0) will represent a cell programmed to a logical ‘0’.

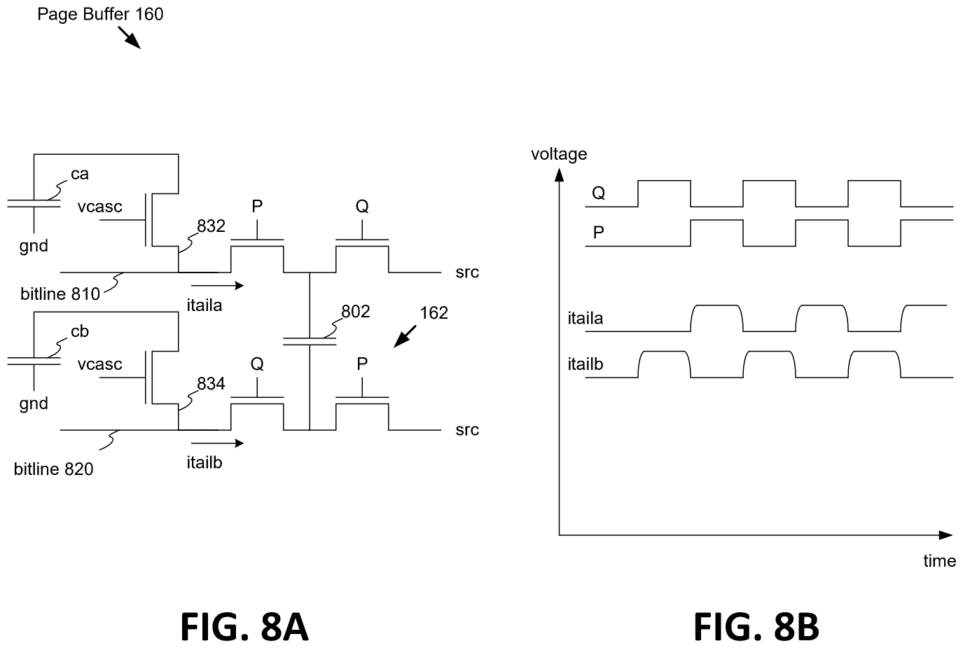

FIG. 8A is a schematic illustrating portions of a page buffer circuit with switched tail current bias circuitry, and FIG. 8B is a timing diagram for the same, in accordance with some embodiments of the present disclosure. For example, the page buffer 160 associated with the memory array 104 of memory device 130 can include tail current bias circuitry 162 corresponding to a pair of bitlines, and thus to a pair of vertical strings of memory cells, in the array 104. In the illustrated embodiment, tail current bias circuitry 162 includes tail current capacitor 802, with one terminal connected to the bitline 810 (i.e., bitline a) in memory array 104 via a network of switches (e.g., transistors), and another terminal that is coupled to bitline 820 (i.e., bitline b) in memory array 104 via a separate network of switches (e.g., transistor). In one embodiment, bitline a is adjacent to bitline b. In one embodiment, the switches of both networks are controlled by alternating control signals (P and Q), as shown in the timing diagram of FIG. 8B. The bitlines 810 and 820 can initially be precharged via a voltage signal received via transistors 832 and 834, respectively, which are controlled by a shared control signal (vcasc). The switches controlled by control signals P and Q alternately charge the tail current capacitor 802 from the bitline 810 and discharge the tail current capacitor to a source node (e.g., ground), thereby generating a tail current (itaila) in bitline 810. In a subsequent cycle, the tail current capacitor 802 is charged from bitline 820 to generate a tail current (itailb) in bitline 820. For example, when the control signal P is active, the tail current (itaila) is generated in bitline 810 to charge tail current capacitor 802, and when the control signal Q is active, the tail current (itailb) is generated in bitline 820 to charge tail current capacitor 802. The frequency of the switching of P and Q can be used to control the magnitude of the tail currents (itaila and itailb). As the voltage on bitlines 810 and 820 reaches a steady state, a signal integration period can begin during which the respective currents can be integrated using respective sense capacitors (ca and cb). The voltage can be sampled during the signal integration period to determine the state of the cell being read on each respective wordline. With this arrangement of tail current bias circuitry 162, one tail current capacitor can be shared by multiple wordlines, thereby decreasing the overall area of the page buffer dedicated to tail current bias, and permitting data from both wordlines to be read in one operation.

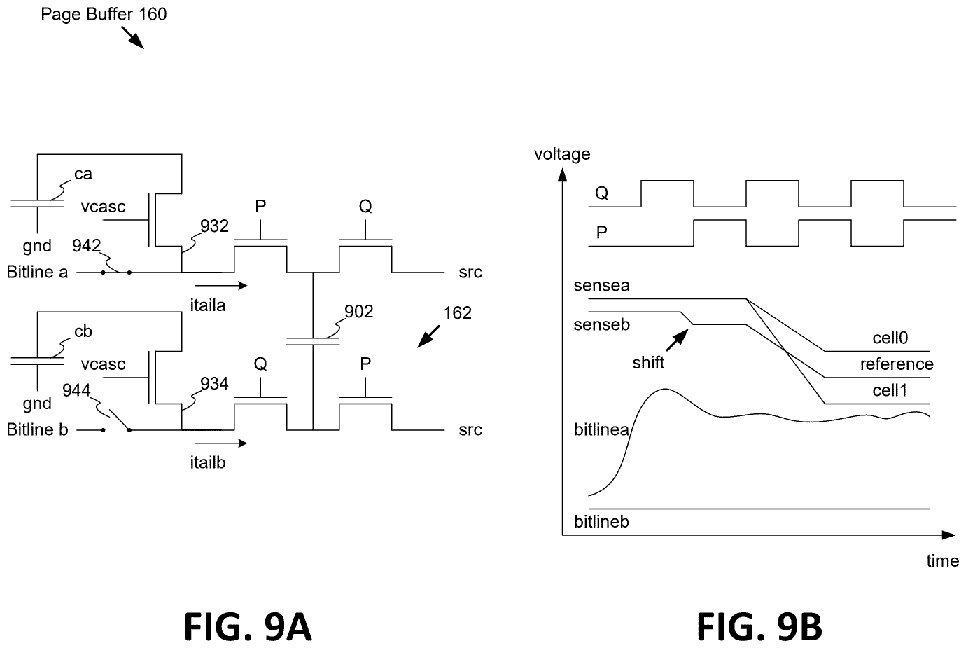

FIG. 9A is a schematic illustrating portions of a page buffer circuit with switched tail current bias circuitry, and FIG. 9B is a timing diagram for the same, in accordance with some embodiments of the present disclosure. For example, the page buffer 160 associated with the memory array 104 of memory device 130 can include tail current bias circuitry 162 corresponding to a pair of bitlines, and thus to a pair of vertical strings of memory cells, in the array 104. In the illustrated embodiment, tail current bias circuitry 162 includes tail current capacitor 902, with one terminal connected to a bitline a in memory array 104 via a network of switches (e.g., transistors), and another terminal that is coupled to a bitline b in memory array 104 via a separate network of switches (e.g., transistor). In one embodiment, bitline a is adjacent to bitline b. In one embodiment, the switches of both networks are controlled by alternating control signals (P and Q), as shown in the timing diagram of FIG. 9B. The bitlines can initially be precharged via a voltage signal received via transistors 932 and 934, respectively, which are respectively controlled by a shared control signal (vcasc). The switches controlled by control signals P and Q alternately charge the tail current capacitor 902 from bitline a and discharge the tail current capacitor to a source node (e.g., ground), thereby generating a tail current (itaila) in bitline a. In a subsequent cycle, the tail current capacitor 902 is charged from bitline b to generate a tail current (itailb) in bitline b. For example, when the control signal P is active, the tail current (itaila) is generated in bitline a to charge tail current capacitor 902, and when the control signal Q is active, the tail current (itailb) is generated in bitline b to charge tail current capacitor 902. The frequency of the switching of P and Q can be used to control the magnitude of the tail currents (itaila and itailb). As the voltage on the bitlines reaches a steady state, a signal integration period can begin during which the respective currents can be integrated using respective sense capacitors (ca and cb). The voltage can be sampled during the signal integration period to determine the state of the cell being read on each respective wordline. In addition, the tail current bias circuitry 162 is connected to bitline a via a separate switch 942 and to bitline b via a separate switch 944. Switches 942 and 944 are controlled using separate control signals from P and Q to provide a self-referencing capability and can be used to independently disconnect the sense circuitry and the tail current bias circuitry from the bitlines. In this manner, tail current bias circuitry 162 can be used to perform a sense operation on either of bitline a or bitline b independently, without having to read data from both bitlines. Thus, the voltage from the respective sense capacitors can be sampled during the signal integration period to determine the state of the cell being read. As illustrated in FIG. 9B, the rate at which the voltage drops can be used to identify the state of the cell being read from the bitlines. A lower voltage (cell1) will represent a cell programmed to a logical ‘1’ and a higher voltage (cell0) will represent a cell programmed to a logical ‘0’. In one embodiment, when a cell associated with bitline a is being sensed, tail current bias circuitry 162 introduces a shift in the voltage of bitline b to move the voltage between that for cell0 and cell1 and create a reference voltage which can be used to discriminate what data is written using a differential approach. When a cell associated with bitline b is sense, the shift can be made in the voltage of bitline a instead.

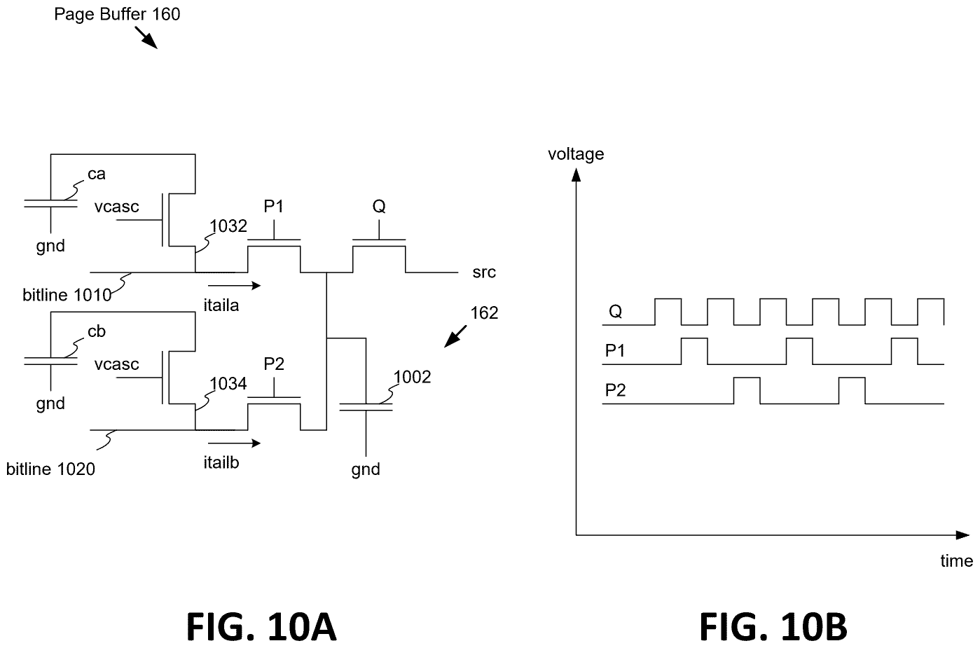

FIG. 10A is a schematic illustrating portions of a page buffer circuit with switched tail current bias circuitry, and FIG. 10B is a timing diagram for the same, in accordance with some embodiments of the present disclosure. For example, the page buffer 160 associated with the memory array 104 of memory device 130 can include tail current bias circuitry 162 corresponding to a pair of bitlines, and thus to a pair of vertical strings of memory cells, in the array 104. In the illustrated embodiment, tail current bias circuitry 162 includes tail current capacitor 1002, with one terminal connected to the bitline 1010 (i.e., bitline a) and the bitline 1020 (i.e., bitline b) in memory array 104 via a shared network of switches (e.g., transistors). In one embodiment, bitline a is adjacent to bitline b. In one embodiment, the switches are controlled by alternating control signals (P1, P2, and Q), as shown in the timing diagram of FIG. 10B. The bitlines 1010 and 1020 can initially be precharged via a voltage signal received via transistors 1032 and 1034, respectively, which are controlled by a shared control signal (vcasc). The switches controlled by control signals P1, P2, and Q alternately charge the tail current capacitor 1002 from the bitline 1-10 and discharge the tail current capacitor to a source node (e.g., ground), thereby generating a tail current (itaila) in bitline 1010. In a subsequent cycle, the tail current capacitor 802 is charged from bitline 1020 to generate a tail current (itailb) in bitline 1020. For example, when the control signal P1 is active, the tail current (itaila) is generated in bitline 1010 to charge tail current capacitor 1002, and when the control signal P2 is active, the tail current (itailb) is generated in bitline 1020 to charge tail current capacitor 1002. When the control signal Q is active, the tail current capacitor 1002 is discharged to the source node (e.g., ground). The frequency of the switching of P1, P2, and Q can be used to control the magnitude of the tail currents (itaila and itailb). For example, the control signal Q may be a frequency that is twice as fast as that of control signals P1 and P2, as shown in the timing diagram of FIG. 10B. As the voltage on bitlines 1010 and 1020 reaches a steady state, a signal integration period can begin during which the respective currents can be integrated using respective sense capacitors (ca and cb). The voltage can be sampled during the signal integration period to determine the state of the cell being read on each respective wordline. With this arrangement of tail current bias circuitry 162, one tail current capacitor can be shared by multiple wordlines, thereby decreasing the overall area of the page buffer dedicated to tail current bias, and permitting data from both wordlines to be read in one operation.

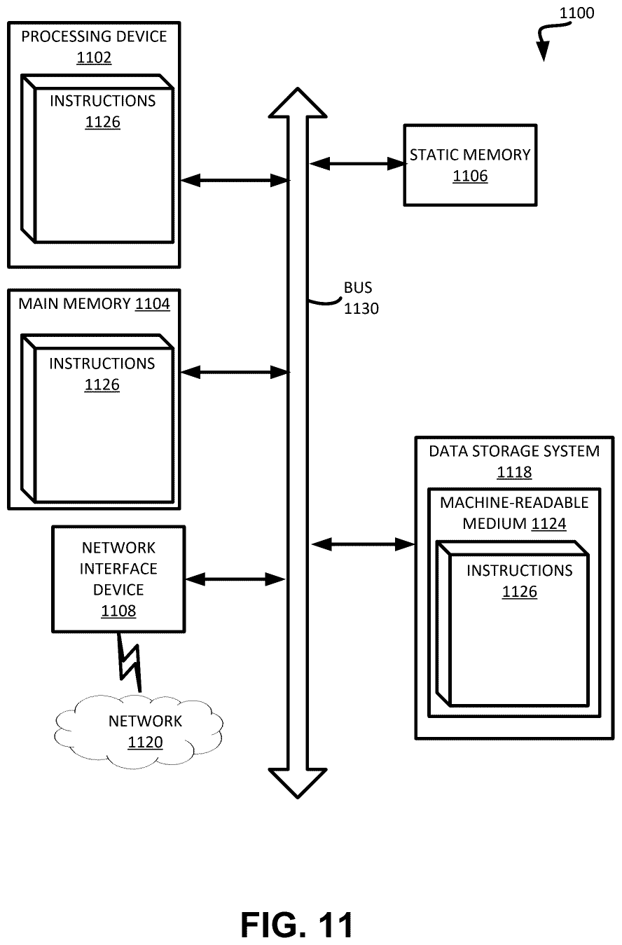

FIG. 11 illustrates an example machine of a computer system 1100 within which a set of instructions, for causing the machine to perform any one or more of the methodologies discussed herein, can be executed. In some embodiments, the computer system 1100 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to memory sub-system controller 115 or local media controller 135 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1100 includes a processing device 1102, a main memory 1104 (e.g., read-only memory (ROM), flash memory, dynamic random access memory (DRAM) such as synchronous DRAM (SDRAM) or Rambus DRAM (RDRAM), etc.), a static memory 1106 (e.g., flash memory, static random access memory (SRAM), etc.), and a data storage system 1118, which communicate with each other via a bus 1130.

Processing device 1102 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1102 can also be one or more special-purpose processing devices such as an application specific integrated circuit (ASIC), a field programmable gate array (FPGA), a digital signal processor (DSP), network processor, or the like. The processing device 1102 is configured to execute instructions 1126 for performing the operations and steps discussed herein. The computer system 1100 can further include a network interface device 1108 to communicate over the network 1120.

The data storage system 1118 can include a machine-readable storage medium 1124 (also known as a computer-readable medium) on which is stored one or more sets of instructions 1126 or software embodying any one or more of the methodologies or functions described herein. The instructions 1126 can also reside, completely or at least partially, within the main memory 1104 and/or within the processing device 1102 during execution thereof by the computer system 1100, the main memory 1104 and the processing device 1102 also constituting machine-readable storage media. The machine-readable storage medium 1124, data storage system 1118, and/or main memory 1104 can correspond to the memory sub-system 110 of FIG. 1A.

In one embodiment, the instructions 1126 include instructions to implement functionality corresponding to memory sub-system controller 115 or local media controller 135 of FIG. 1A. While the machine-readable storage medium 1124 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of memory cells formed at respective intersections of a plurality of wordlines and a plurality of bitlines; and
a page buffer circuit coupled to the memory array, the page buffer circuit comprising sense circuitry to measure a cell current read from a bitline of the plurality of bitlines and tail current bias circuitry coupled to the bitline, wherein the tail current bias circuitry comprises a tail current capacitor having a first terminal coupled to the bitline, the tail current capacitor to generate a tail current in the bitline during a signal integration period when the sense circuitry measures the cell current read from the bitline.

2. The memory device of claim 1, wherein the sense circuitry comprises a cascode transistor coupled to the bitline, a temporary cache capacitor coupled to a temporary cache node, and a detector transistor coupled to the temporary cache node, and wherein the temporary cache transistor is to integrate the cell current measured from the bitline during the signal integration period.

3. The memory device of claim 2, wherein a bias voltage applied to a second terminal of the tail current capacitor is ramped down over time to generate the tail current in the bitline.

4. The memory device of claim 3, wherein the tail current bias circuitry comprises a second tail current capacitor having a first terminal coupled to the temporary cache node and a second terminal to receive the bias voltage, wherein the second tail current capacitor is to generate a second tail current in the bitline during the signal integration period.

5. The memory device of claim 2, wherein the tail current capacitor is coupled to the bitline by a plurality of switches, and wherein the plurality of switches are controlled by alternating control signals to alternately generate the tail current in the bitline to charge the tail current capacitor and discharge the tail current capacitor to a source node.

6. The memory device of claim 5, wherein the tail current bias circuitry comprises a plurality of tail current capacitors coupled to the bitline by the plurality of switches.

7. The memory device of claim 5, wherein the tail current capacitor is coupled between the bitline and an adjacent bitline by the plurality of switches.

8. The memory device of claim 7, wherein the bitline and the adjacent bitline comprise respective self-referencing switches to independently disconnect the sense circuitry and the tail current bias circuitry.

9. A page buffer circuit comprising:
sense circuitry to measure a cell current read from a bitline of a plurality of bitlines of a memory array; and
tail current bias circuitry coupled to the bitline, wherein the tail current bias circuitry comprises a tail current capacitor having a first terminal coupled to the bitline, the tail current capacitor to generate a tail current in the bitline during a signal integration period when the sense circuitry measures the cell current read from the bitline.

10. The page buffer circuit of claim 9, wherein the sense circuitry comprises a cascode transistor coupled to the bitline, a temporary cache capacitor coupled to a temporary cache node, and a detector transistor coupled to the temporary cache node, and wherein the temporary cache transistor is to integrate the cell current measured from the bitline during the signal integration period.

11. The page buffer circuit of claim 10, wherein a bias voltage applied to a second terminal of the tail current capacitor is ramped down over time to generate the tail current in the bitline.

12. The page buffer circuit of claim 11, wherein the tail current bias circuitry comprises a second tail current capacitor having a first terminal coupled to the temporary cache node and a second terminal to receive the bias voltage, wherein the second tail current capacitor is to generate a second tail current in the bitline during the signal integration period.

13. The page buffer circuit of claim 10, wherein the tail current capacitor is coupled to the bitline by a plurality of switches, and wherein the plurality of switches are controlled by alternating control signals to alternately generate the tail current in the bitline to charge the tail current capacitor and discharge the tail current capacitor to a source node.

14. The page buffer circuit of claim 13, wherein the tail current bias circuitry comprises a plurality of tail current capacitors coupled to the bitline by the plurality of switches.

15. The page buffer circuit of claim 13, wherein the tail current capacitor is coupled between the bitline and an adjacent bitline by the plurality of switches.

16. The page buffer circuit of claim 15, wherein the bitline and the adjacent bitline comprise respective self-referencing switches to independently disconnect the sense circuitry and the tail current bias circuitry.

17. A memory device comprising:
a memory array comprising a plurality of memory cells formed at respective intersections of a plurality of wordlines and a plurality of bitlines;
a page buffer circuit coupled to the memory array, the page buffer circuit comprising sense circuitry to measure a cell current read from a bitline of the plurality of bitlines and tail current bias circuitry coupled to the bitline, wherein the tail current bias circuitry comprises a tail current capacitor having a first terminal coupled to the bitline, the tail current capacitor to generate a tail current in the bitline during a signal integration period when the sense circuitry measures the cell current read from the bitline; and
control logic, operatively coupled to the memory array and the page buffer circuit, to perform operations comprising:
causing the bitline to be precharged;
causing a read voltage to be applied to a wordline of the plurality of wordlines; and
causing a bias voltage applied to a second terminal of the tail current capacitor to be ramped down over time to generate the tail current in the bitline.

18. The memory device of claim 17, wherein the sense circuitry comprises a cascode transistor coupled to the bitline, a temporary cache capacitor coupled to a temporary cache node, and a detector transistor coupled to the temporary cache node.

19. The memory device of claim 18, wherein the control logic is to perform operations further comprising:
causing the temporary cache transistor to integrate the cell current measured from the bitline during the signal integration period.

20. The memory device of claim 19, wherein the tail current bias circuitry comprises a second tail current capacitor having a first terminal coupled to the temporary cache node and a second terminal to receive the bias voltage, wherein the second tail current capacitor is to generate a second tail current in the bitline during the signal integration period.
